(19) United States
(12) Patent Application Publication
(10) Pub. No.: US 2026/0190380 A1
(43) Pub. Date: Jul. 2, 2026

(54) HIGH-K/METAL GATE LDMOS NANOSHEET DEVICE

(71) Applicant: Texas Instruments Incorporated, Dallas, TX (US)

(72) Inventors: Daniel Pham, Celina, TX (US); Henry Litzmann Edwards, Garland, TX (US); Sujatha Sampath, Salt Lake City, UT (US); Ali Saadat, Santa Clara, CA (US); Orlando Lazaro, Cary, NC (US); Vijay K. Reddy, Plano, TX (US); Steven Kummerl, Carrollton, TX (US)

(21) Appl. No.: 19/003,730

(22) Filed: Dec. 27, 2024

(51) Int. Cl. H10D 30/65; H10D 30/00; H10D 30/01

(52) U.S. Cl. CPC H10D 30/65; H10D 30/0191; H10D 30/0281; H10D 30/501

(57) ABSTRACT

Disclosed examples include microelectronic devices, e.g., integrated circuits and methods of making such devices. One example includes a microelectronic device including a nanosheet laterally-diffused metal oxide semiconductor (LDMOS) transistor. The LDMOS transistor may include a high-k gate dielectric and a metal gate. The (LDMOS) transistor includes source and drain regions having a first conductivity type that extend into a semiconductor substrate. A nanosheet region including semiconducting nanosheets extends between the source region and the drain region. The nanosheets alternate with gate conductor layers that extend between the source region towards the drain region and field plate conductor layers that extend from the drain region towards the source region with gate dielectric layers and field relief dielectric layers separating the gate conductor layers from the field plate conductor layers.

### TECHNICAL FIELD

This disclosure relates to the field of microelectronic devices. More particularly, but not exclusively, this disclosure relates to gated devices such as LDMOS transistors and in particular nanosheet LDMOS transistors.

### BACKGROUND

Semiconductor components are being continually improved to reliably operate with smaller feature sizes. Fabricating semiconductor devices that have increasingly higher performance while meeting performance and reliability specifications presents diverse challenges.

### SUMMARY

This summary is provided to introduce a brief overview of disclosed concepts in a simplified form that are further described below in the detailed description including the drawings provided. This summary is not intended to limit the scope of the disclosure or the claims.

Disclosed examples include microelectronic devices, e.g. integrated circuits and methods of making such devices. One example includes a microelectronic device including a nanosheet laterally-diffused metal oxide semiconductor (LDMOS) transistor. The LDMOS transistor may include a high-k gate dielectric and a metal gate. The LDMOS transistor includes source and drain regions having a first conductivity type that extend into a semiconductor substrate. A nanosheet region including semiconducting nanosheets extends between the source region and the drain region. The nanosheets alternate with gate conductor layers that extend between the source region towards the drain region and field plate conductor layers that extend from the drain region towards the source region with gate dielectric layers and field relief dielectric layers separating the gate conductor layers from the field plate conductor layers.

### BRIEF DESCRIPTION OF THE VIEWS OF THE DRAWINGS

FIGS. 1A and 1B respectively show a perspective view and a top-down view of an example microelectronic device including a nanosheet LDMOS transistor with a field plate;

FIGS. 1C and 1D respectively show a longitudinal section view and a transverse section view of the microelectronic device of FIG. 1A;

FIGS. 2A-15A, 16, 17A-19A, and 20-22 show longitudinal sectional views of the microelectronic device of FIG. 1A in various states of formation; and

FIGS. 2B-15B, and 17B-19B show various transverse sectional views of the microelectronic device of FIG. 1A in various states of formation.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events unless otherwise stated. Furthermore, some of the illustrated acts or events may be omitted in some examples in accordance with the present disclosure.

In addition, although some of the examples illustrated herein are shown in two dimensional views with various regions having depth and width, it should be clearly understood that these regions are illustrations of only a portion of a device that is actually a three-dimensional structure. Accordingly, these regions will have three dimensions, including length, width, and depth, when fabricated on an actual device. Moreover, while the present disclosure may be illustrated by examples directed to active devices, it is not intended that these illustrations be a limitation on the scope or applicability of the present disclosure. It is not intended that the active devices of the present disclosure be limited to the physical structures illustrated. These structures are included to demonstrate the utility and application of the present disclosure to various examples.

It is noted that terms such as top, bottom, over, above, and under may be used in this disclosure. These terms should not be construed as limiting the position or orientation of a structure or element, but should be used to provide spatial relationship between structures or elements. The terms “lateral” and “laterally” refer to directions parallel to a plane corresponding to a surface of a layer, for example a top surface of a semiconductor substrate. Moreover, the term “approximately,” unless stated otherwise, means ±10% variations of the recited values. The term “about” means within ±20% of a recited values.

Microelectronic devices are being continually improved to reliably operate with higher performance and smaller feature sizes. Fabricating such microelectronic devices satisfying area scaling and reliability specifications presents ongoing challenges. Some gate-controlled devices such as metal-oxide-semiconductor (MOS) transistors include features for supporting high voltage operations, e.g., with a voltage applied to their drain (or drain structure) of 20 V, 30 V, 40 V, or even greater. Such MOS transistors may include drain diffusion profiles (or drain junction profiles) devised to support the high voltages applied to the drain, e.g., having an extended portion to distribute the voltage drop across greater distances. Accordingly, such MOS transistors may be referred to as extended drain (ED) MOS transistors, for example drain-extended n-channel MOS (DENMOS) transistors, drain-extended p-channel MOS (DEPMOS) transistors, laterally-diffused MOS (LDMOS) transistors, as well as groups of DENMOS and DEPMOS transistors (which may be referred to as complimentary drain-extended MOS or DECMOS transistors). Other gate controlled microelectronic devices may include a gated bipolar semiconductor device, a gated unipolar semiconductor device, an insulated gate bipolar transistor (IGBT), a MOS-triggered SCR, a MOS-controlled thyristor, and a gated diode. ED transistors are scaled down to smaller sizes to reduce microchip cost and improve circuit performance by reducing parasitic resistance and capacitance. It can be challenging to maintain good reliability and yield, so it may be advantageous to improve transistor performance independently of lateral lithographic scaling.

The physical geometry of the nanosheets for ED transistors differs from those in nanosheet digital CMOS transistors. For example, in general some nanosheet digital (switching) CMOS transistors may use a nanosheet architecture including nanosheet layers just a few nanometers thick. Due to the relatively thin conduction path, such nanosheet layers may have reduced carrier mobility which may not be relevant to switching applications. For high voltage ED transistors, however, drain drift region mobility may be beneficial, and nanosheets thicker than 10 nm, such as in the range from 20 nm to 500 nm or greater, may be used to achieve target RSP values for efficient power circuit design. In some examples, the nanosheet thickness could be 50 nm to 500 nm, or 100 nm to 300 nm, which may keep the drain drift region doping concentration low enough to preserve high electron mobility, hence low RSP. Furthermore, example nanosheet ED transistors of the disclosure may have a drain drift region with field relief structures to provide higher voltage operation than possible for nanosheet switching transistors.

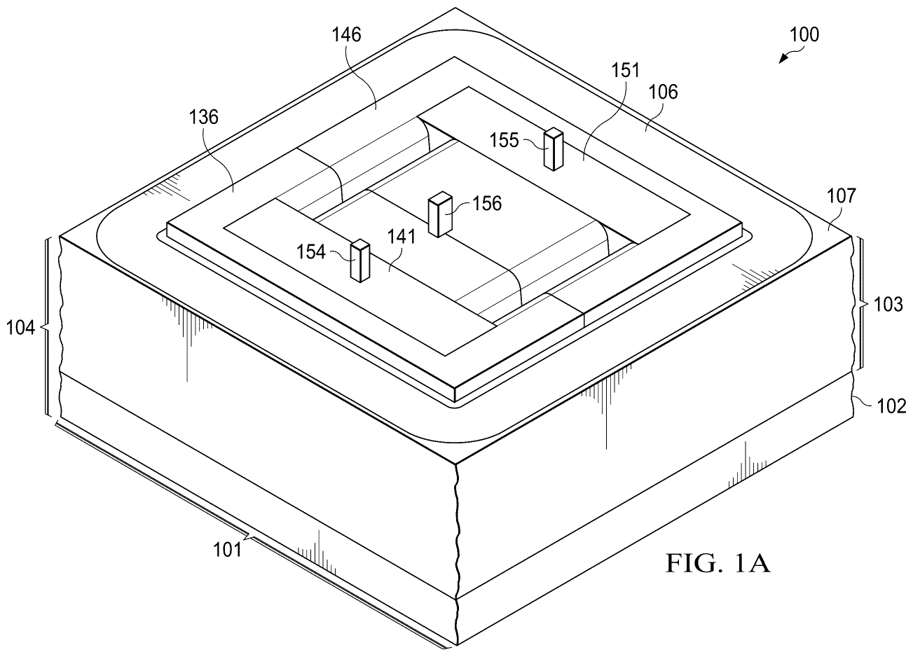

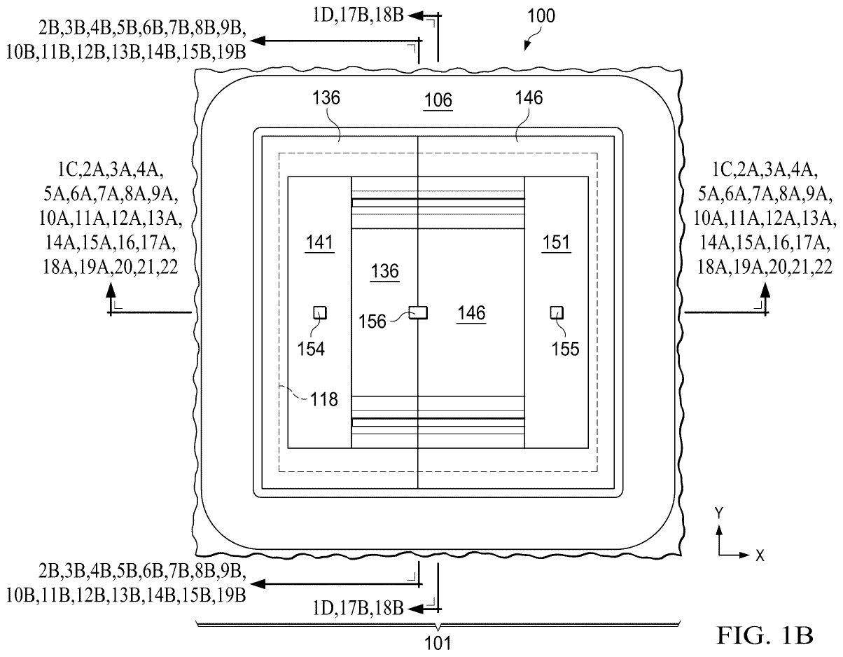

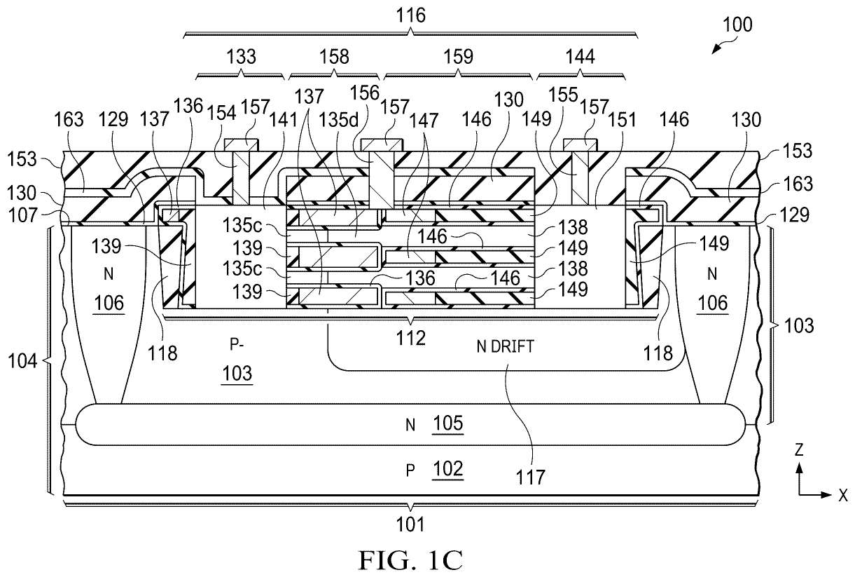

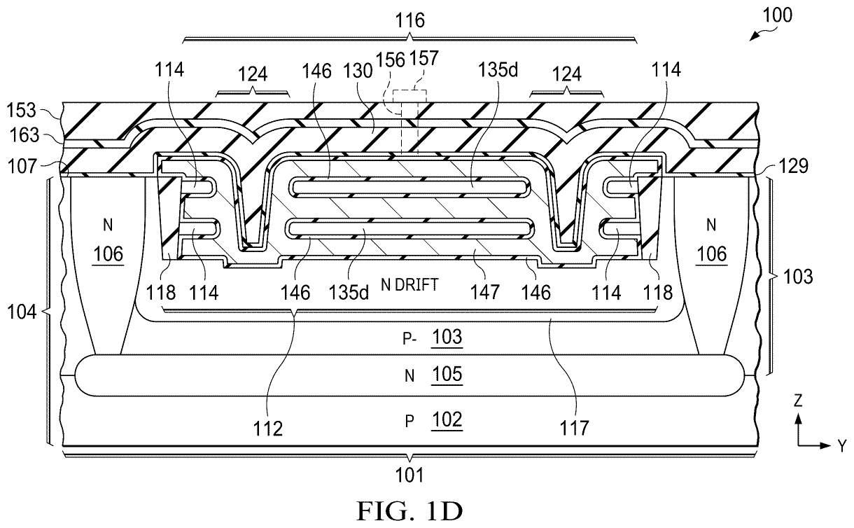

Stacking multiple transistor channels may be advantageous by reducing on-resistance of an ED transistor may generally be decreased, and the and increasing on-current increased, by increasing the width of the channel and drift regions between the source and the drain. For a planar transistor, such a transistor design may use more die area than preferred. Examples of the disclosure provide increased channel and drift region width by using multiple vertically-stacked nanosheet channels between the source and the drain. Proportionally to the number of layers stacked. An example ED transistor as described in FIGS. 1A-1DL and 1T may have nanosheet drift regions with a nanosheet region doping profile whose a dopant concentration dose lies in the resurf range of 10¹²-10¹³ cm⁻², which sets the drain drift region contribution to source-drain on resistance (RDSON), which often is the dominant contribution to device resistance. Therefore, stacking multiple nanosheets ED transistors in parallel enables the reduction of RDSON of the ED transistor in a given area, so that the cost figure of merit specific on- resistance (RSP) cost figure of merit, e.g. which is equal to the RDSON times the area, is reduced and power technology scaling can be improved for a given lithographic scaling capability.

In some examples the present disclosure describes devices including a gate dielectric layer between a semiconductor channel of a nanosheet layer in a gate region, and a field relief dielectric layer thicker than the gate dielectric layer between a drift region of the nanosheet layer in the drift region. Either or both of the gate dielectric layer and the field relief dielectric layer may be silicon oxide (k≈3.9) or a dielectric material with a higher dielectric constant than silicon oxide, and may one or both of the gate dielectric layer and the field relief dielectric layer may have a single layer or two or more sublayers with an overall dielectric constant greater than 3.9 The use of field relief dielectric layer in the drift region thicker than the gate dielectric layer may result in higher breakdown voltage of the device and consequently allow higher voltage operation of the device compared to a device with a thinner field relief dielectric layer.

In a conventional, e.g., planar, drain extended device, a thicker dielectric with different geometries such as LOCOS, STI, etc. is sometimes needed over the drift region for higher voltage rating transistors. In the present disclosure, the gate dielectric layer and the field relief dielectric layer contact each other and form a continuous dielectric block or dielectric spacer between a conductive layer acting as a gate electrode, on the source side of the transistor and a conductive layer acting as a field plate on the drain side of the transistor. The dielectric block between the gate layer and the field plate layer may improve hot carrier performance and thus improve reliability. The dielectric block also allows for implementing a field plate layer with a different work function than the gate layer on the channel side of the transistor. The ability to have separate gate metals over the channel and the field plate may enable a field relief dielectric layer that is thinner than might otherwise be required for a given high voltage operation condition. The gate metal may have a work function greater than 3.9 eV. The gate metal may be TiAlN, TiN, TaN, Al, TaSiN, MoN and W or other appropriate metal.

The disclosure includes an example microelectronic device including a nanosheet LDMOS transistor incorporating a high-k gate dielectric layer, a high-k field relief dielectric layer, and gate layer and a field plate layer with a work function greater than 3.9 eV. As used herein the term “superlattice” means a periodic structure of layers of at least two different materials. A superlattice may have many such layers, and in some cases may have as few as two layers including a layer of a first material and a layer of a second material. Such layers may be referred to as “nanosheets,” which may have a thickness (in a direction normal to the major surface of a substrate over which the superlattice is formed) no greater than 500 nm. A nanosheet may also be an active layer of a semiconductor device including the nanosheet. The superlattice may initially include one or mode “sacrificial layers” formed in the superlattice, of which all or a portion of which may be removed later in the formation of the nanosheet transistor.

While such examples of the disclosure may be expected to provide improved performance, such as reduced specific RSP, RSON and greater on-current, reduced die area to implement various devices, and/or higher operating voltage than some otherwise comparable baseline planar devices, no particular result is a requirement of the present disclosure unless explicitly recited in a particular claim.

FIG. 1A shows a perspective view of a microelectronic device 100, e.g., including a nanosheet LDMOS transistor 101, sometimes referred to as a nanosheet transistor 101 or simply transistor 101 for brevity, to which the principles of the disclosure may be beneficially applied. FIG. 1B shows a top-down view with orientations shown for cross-sectional views of FIGS. 1C and 2A-15A, 16, 17A-19A and 20A-22A in the longitudinal plane of the microelectronic device 100 at various stages of formation, and for cross-sectional views of FIGS. 1D, 2B-16B and 17B-19B, in the transverse plane at various stages of formation. FIG. 1C is a section view of the microelectronic device 100 through a longitudinal plane, and FIG. 1D is a section view through a transverse plane.

The perspective view of FIG. 1A is shown with some layers removed for clarity. The nanosheet transistor 101 is formed in or over semiconductor substrate 104 that includes a base wafer 102, such as a silicon wafer, and a, that has a top surface 107 and may have a thickness of 5 μm to 15 μm by way of example. A source contact 154 electrically connects to a source region 141, and a drain contact 155 electrically connects to a drain region 151. The source regions 141 and drain regions 151 have a first conductivity type which in various examples is n-type. The semiconductor material 103 has a second conductivity type, which in various examples is p-type. A gate contact 156 connects to an underlying gate electrode as described further below. Isolation of the transistor 101 is provided by a deep well 106 that surrounds the gate dielectric layers 136 and the field relief dielectric layers 146, and extends to a buried layer, also described further below. The deep well 106 may sometimes be referred to as a deep well ring. While only a single source region 141 and a single drain region 151 are shown, example devices consistent with the disclosure may have multiple source regions 141 and drain regions 151, with corresponding nanosheet regions 116, which may provide parallel conduction.

FIG. 1B illustrates in plan view some of the features of the transistor 101 illustrated in FIG. 1A, including a shallow trench isolation (STI) structure 118 shown surrounded by the deep well 106 that also contributes to the device isolation. This figure also provide various references for cross-sections shown in various figures described below. FIGS. 1C, 2A-15A, 16, 17A-19A, and 20-22 show the transistor 101 in various stages of formation along a longitudinal direction in a plane (X-Z) parallel to a direction from the source contact 154 to the drain contact 155, and FIGS. 1D, 2B-15B and 17B-19B show the transistor 101 in various stages of formation along a transverse direction in a plane (Y-Z) normal to the longitudinal direction.

Referring to FIG. 1C and FIG. 1D, described concurrently, the nanosheet transistor 101 is shown at a late stage of formation. The deep well 106 extends from the top surface 107 through the semiconductor material 103, which has the first conductivity type, to a buried layer 105 having the first conductivity type, sometimes referred to as an n-type buried layer, or NBL 105. A “buried layer,” sometimes abbreviated “BL,” is defined as a semiconductor layer having a first doping characteristic, e.g., conductivity type, dopant type or dopant concentration, such as the NBL 105, spaced apart from the top surface 107 by another layer having a different second doping characteristic, such as the semiconductor material 103. The NBL 105 and the ring of deep well 106 together define an isolation region in which the transistor 101 is located. A nanosheet region 116 includes a source trench 133 that includes the source region 141, a drain trench 144 that includes the drain region 151, a gate electrode region 158 and a field plate region 159. P-type nanosheet channel layers 135c extend from the source region 141 toward the drain region 151, and n-type nanosheet drain drift layers 138 extend from the drain region 151 toward the source region 141. The source region 141, the drain region 151, channel layers 135c and drain drift layers 138 are in a nanosheet trench 112 sometimes referred to for brevity as trench 112.

Gate electrode layers 137 extend from the gate contact 156 toward the source region 141, and field plate layers 147 extend from the gate contact 156 toward the drain region 151. The gate electrode layers 137 are laterally spaced apart from the source region 141 by gate electrode spacers 139, and the field plate layers 147 are laterally spaced apart from the drain region 151 by field plate spacers 149. The channel layers 135c are located between vertically adjacent ones of the gate electrode spacers 139 and gate electrode layers 137. The drain drift layers 138 are in an n-type drain drift region 117, sometimes referred to as an NDRIFT region 117, and extend from the drain region 151 to the channel layers 135c between vertically adjacent ones of the field plate spacers 149 and field plate layers 147. A thicker portion of the drain drift layers 138 extends to a source-side end of the field plate layers 147, and a thinner portion of the drain drift layers 138 extends from the thicker portion to the channel layers 135c. The thinner portion of the drain drift layers 138 and the channel layers 135c have substantially the same thickness. A longitudinal length (X-direction) of the thinner portion may be as small as zero, or may be a significant fraction of the longitudinal width of the gate electrode layer 137, e.g., 50% or more as in the illustrated example.

The gate dielectric layer 136 is located between each of the gate electrode layers 137 and a vertically adjacent channel layer 135c, and in some examples between the gate electrode layers 137 and a thinner portion of a vertically adjacent drain drift layer 138. In some examples, such as illustrated, the gate electrode layers 137 are covered on three sides by an unbroken, conformal gate dielectric layer 136.

Between the source region 141 and the STI structure 118 a portion of the gate dielectric layer 136 contacts the STI structure 118, and a portion of the gate electrode spacer 139 is between the source region 141 and the gate dielectric layer 136. These features are artifacts of the process of forming the transistor 101 and are not expected to significantly contribute to the functional properties of the transistor 101. Additionally, a portion of the gate dielectric layer 136 and a portion of the gate electrode layer 137 above the STI structure 118 are artifacts of the process of forming the transistor 101 and negligibly contribute to the functional properties of the transistor 101.

Additional features of the transistor 101, a third pad oxide layer 129, a third hard mask layer 130, a fourth hard mask layer 163, and a dielectric layer 153, sometimes referred to as a pre-metal dielectric layer 153. Metal terminals 157 over the PMD layer 153 provide electrical connection to the source contact 154, drain contact 155 and gate contact 156.

In the field plate region 159, the field relief dielectric layer 146 contacts the drain drift layers 138. The field plate layer 147 contacts the field relief dielectric layer 146. In the region where the gate electrode region 158 and the field plate region 159 meet, the gate dielectric layer 136 and the field plate layer 147 provide electrical isolation between the gate electrode layer 137 and the field plate layer 147. The field plate spacers 149 provide electrical isolation between the field plate layer 147 and the drain region 151. Between the source region 141 and the STI structure 118 a portion of a third pad oxide layer 129, contacts the STI structure 118, and a portion of the field plate spacers 149 is between the drain region 151 and the third pad oxide layer 129, neither of the layers being functional elements of the nanosheet transistor 101.

In addition to the described features of the transistor 101, trenches 124 are shown in FIG. 1D that are related to certain sacrificial layer(s) described below used to form the transistor 101.

Various structural features of the microelectronic device 100 and steps of formation are now described in the context of sequential longitudinal or transverse sectional views at various stages of formation.

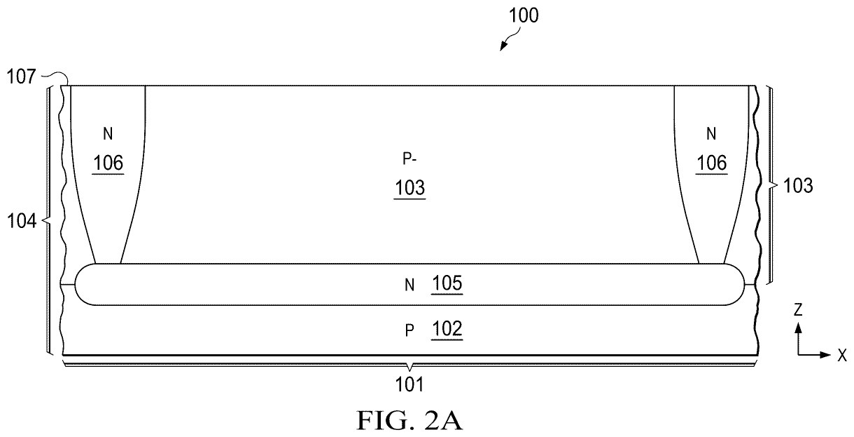

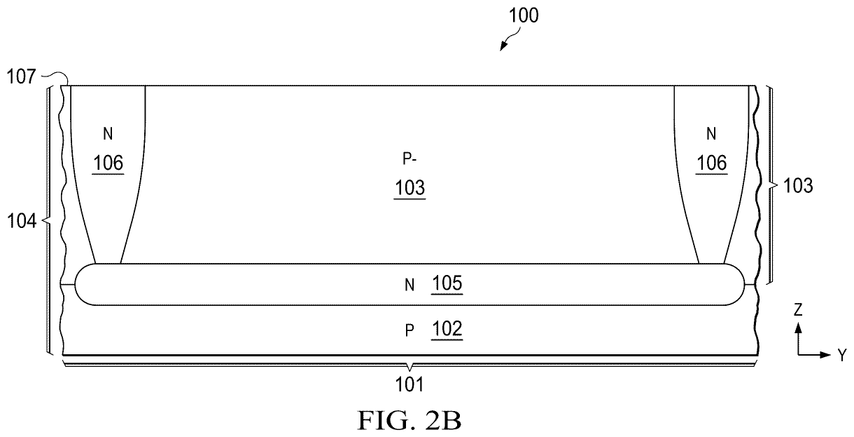

Referring to FIG. 2A and FIG. 2B, the microelectronic device 100 is shown in an early stage of formation. The base wafer 102 may be a silicon wafer having any conductivity type. In some other examples, the base wafer 102 may include a dielectric material, such as silicon dioxide or sapphire, to provide a silicon-on-insulator (SOI) substrate. A semiconductor material 103 has been formed on the base wafer 102. In various examples the semiconductor material 103 includes primarily silicon, and may consist essentially of silicon and dopants, such as boron, in which case has the semiconductor material is p-type. The semiconductor material 103 may be formed by an epitaxial process and may be 5 μm to 15 μm by way of example. The semiconductor material 103 extends to a top surface 107. The base wafer 102 and the semiconductor material 103 form the substrate 104 herein referred to as a substrate 104.

In some examples, and as shown, the buried layer 105 extends into both the base wafer 102 and the semiconductor material 103. The buried layer 105 has the first conductivity type, n-type in this example, and as such may be referred to without limitation as an n-type buried layer, or NBL 105. The NBL 105 may be formed by any conventional or heretofore undiscovered method. In one such example, dopants of the second conductivity type, such as phosphorus, arsenic, or antimony, are deposited into the base wafer 102 before the semiconductor material 103 is formed. The base wafer 102 may be annealed prior to forming the semiconductor material 103, and the semiconductor material 103 may subsequently be formed by an epitaxial process of thermal decomposition of silane, during which the dopants diffuse deeper into the base wafer 102 and into the semiconductor material 103, forming the NBL 105.

The deep well 106 may be formed in the semiconductor material 103, extending from the top surface 107 of the substrate 104 to the NBL 105. The deep well 106 may have the first conductivity type, e.g., n-type. The deep well 106 may be formed by implanting dopants of the first conductivity type, such as phosphorus, into the semiconductor material 103, followed by a thermal drive to diffuse the implanted dopants to the NBL 105 and activate the implanted dopants. The deep well 106 may have an average concentration of the dopants of the first conductivity type that is at least 2 times to 10 times greater than an average concentration of dopants of the second conductivity type in the semiconductor material 103 outside of the deep well 106. The deep well 106 provides isolation between the nanosheet transistor 101 and other components of the microelectronic device 100. The deep well 106 may preferably be degenerately doped to provide low leakage between the nanosheet transistor 101 and other components of the microelectronic device 100.

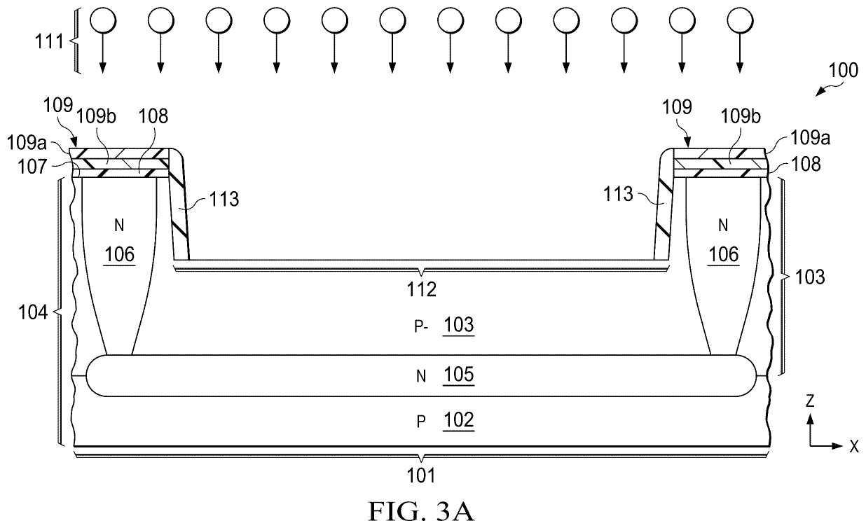

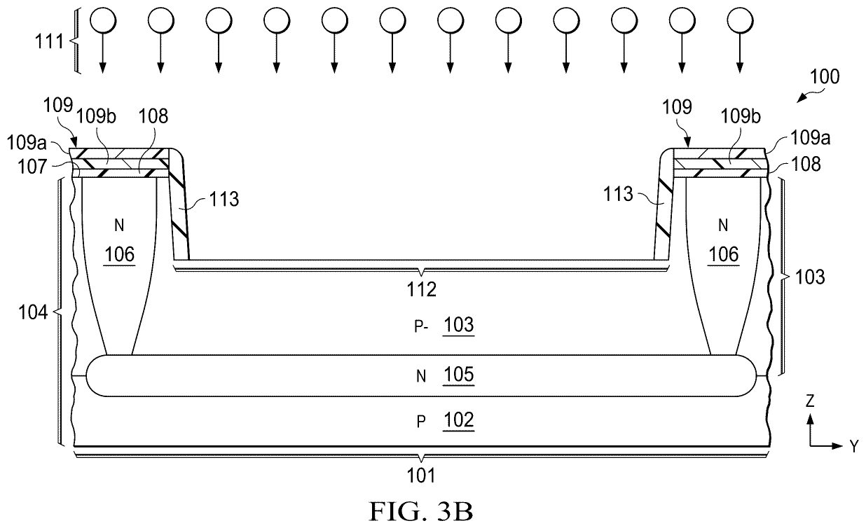

FIG. 3A and FIG. 3B show the microelectronic device 100 after a trench 112 has been formed. After formation of the NBL 105 and the deep well 106, first pad oxide layer 108 may be formed on the top surface 107 of the substrate 104. The first pad oxide layer 108 may include primarily silicon dioxide, may be formed by a thermal oxidation process or a thermal chemical vapor deposition (CVD) process, and may have a thickness of 5 nm to 200 nm, by way of example. A first hard mask layer 109 may be formed on the first pad oxide layer 108. The first hard mask layer 109 may include a layer 109a of a material composed primarily of silicon nitride, and a layer 109b of a material containing primarily silicon dioxide. The first hard mask layer 109 may have a thickness of 50 nm to 3 μm, depending on a depth of the trench 112. The first pad oxide layer 108 may provide stress relief between the semiconductor material 103 and the first hard mask layer 109. The silicon nitride portion of the first hard mask layer 109 may provide a stop layer for subsequent etch and planarization processes. The silicon dioxide layer of the first hard mask layer 109 may provide a hard mask during a trench etch 111 to form the trench 112. A trench photomask (not specifically shown) may be formed on the first hard mask layer 109 with openings which expose the first hard mask layer 109 in areas for the trench 112.

The trench etch 111 forms the trench 112 in the substrate 104. The trench etch 111 may include multiple steps. After the trench etch 111, the trench photomask is removed. A trench sidewall spacer 113 is formed after the trench photomask is removed. The trench sidewall spacer 113 may be formed by depositing a blanket layer of a dielectric such as silicon dioxide or silicon nitride, followed by an anisotropic etch (neither process specifically shown). The anisotropic etch leaves the trench sidewall spacer 113 which prevents deposition of semiconductor material on the trench 112 sidewalls in a subsequent processing step. After the formation of the trench sidewall spacer 113, the horizontal surface of the trench 112 is generally free of dielectric material.

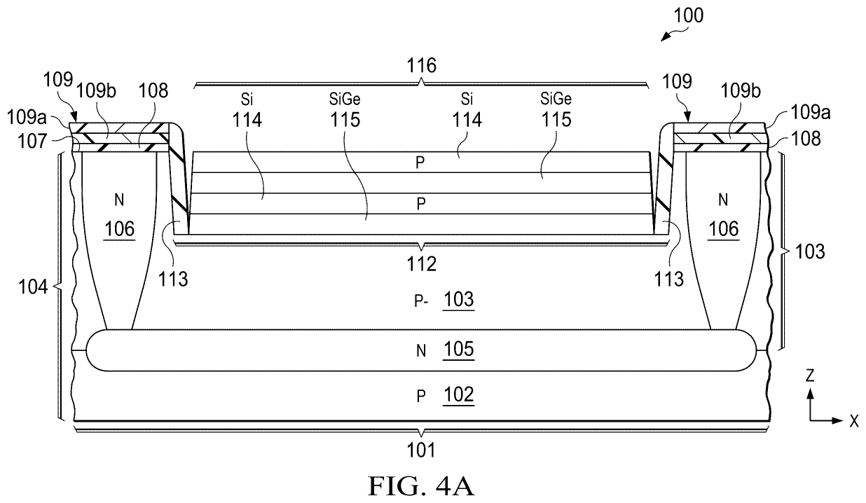

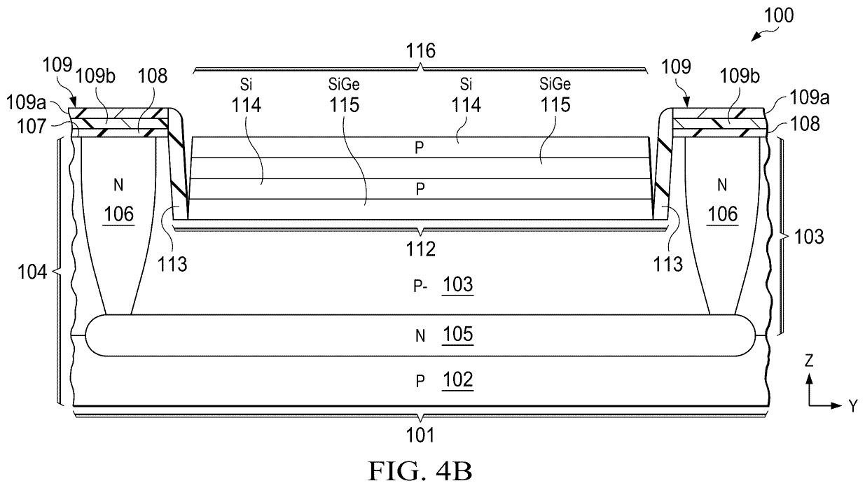

Referring to FIG. 4A and FIG. 4B, cross sections are shown after a nanosheet region 116 has been formed. The nanosheet region 116 may be formed by epitaxial deposition or atomic-layer deposition (ALD) or other deposition method to form semiconductor layers 114 alternating with sacrificial layers 115. In the example nanosheet transistor 101, the semiconductor layers 114 may be primarily monocrystalline silicon, for example p-type doped in-situ, and the sacrificial layers 115 may be primarily monocrystalline SiGe, for example undoped, or intrinsic. Other examples within the scope of the disclosure may use other combinations of semiconductor layers 114 and sacrificial layers 115. For example, the roles of silicon and SiGe may be reversed such that SiGe is used as the semiconductor material of the semiconductor layers 114 and silicon is used as the sacrificial layers 115. Other combinations may also be used, where the materials may be formed in the alternating layers, and one layer may be preferentially removed leaving the semiconductor layers 114 intact. Without implied limitation the semiconductor layers may be referred to as silicon layers 114. The silicon layers 114 may have a thickness in a range between about 10 nm and about 500 nm, though other thicknesses are contemplated. The materials of which the silicon layers 114 and sacrificial layers 115 are realized may be chosen such that the sacrificial layer 115 may be removed at a later stage of processing by a plasma etch or wet etch process while the silicon layers 114 remains intact.

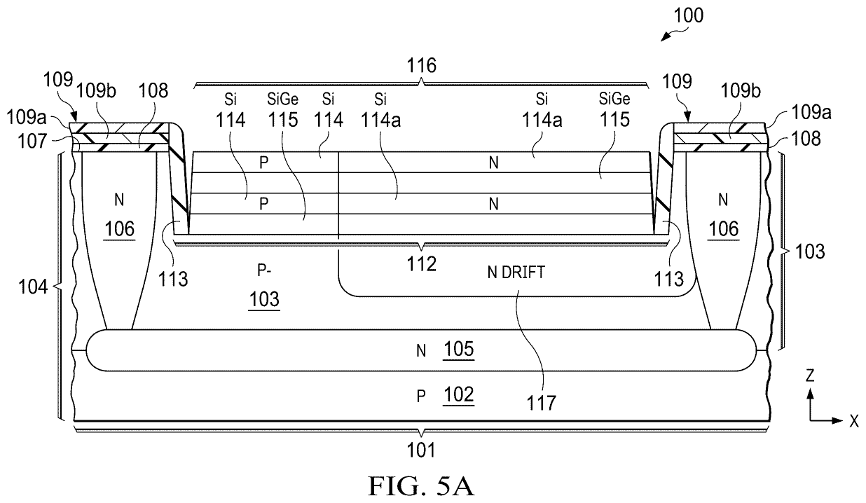

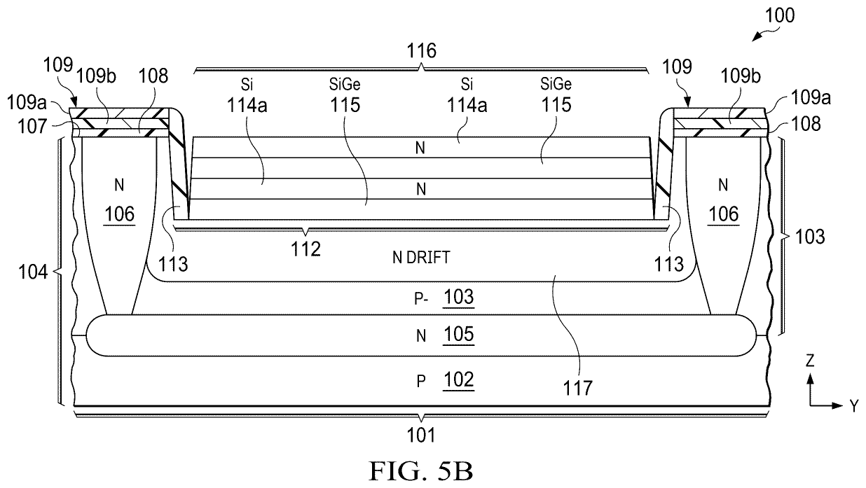

FIGS. 5A and 5B show the transistor 101 after forming NDRIFT region 117 An n-type dopant such as phosphorous may be implanted at least as deep as the bottom of the trench 112, optionally using a chain implant to result in an effectively uniform dopant distribution in the NDRIFT region 117 after an activation anneal. Portions of the silicon layers 114 within the NDRIFT region 117 are converted from p-type to n-type nanosheet drain drift layers 138, and may be referred to as n-doped silicon layers 114a to reflect the modification. The n-type and p-type portions may be referred to collectively as silicon layers 114 when further distinction is unneeded.

The NDRIFT region 117 is formed in the substrate 104, in the semiconductor material 103, a portion of the nanosheet region 116, and will subsequently surround the drain region 151 illustrated in FIG. 1C. One or more n-type implants are performed to form the drain drift region 117 (which may be referred to as an n-drift region) in the substrate 104. The n-type dopant that defines the n-drift region 117 may be implanted in one step or in multiple steps. Arsenic may also be implanted with a similar dose with an energy relatively higher than the phosphorus implant. The NDRIFT region 117 has an average doping concentration lower than the average doping concentration of the drain region 151 (FIG. 1C).

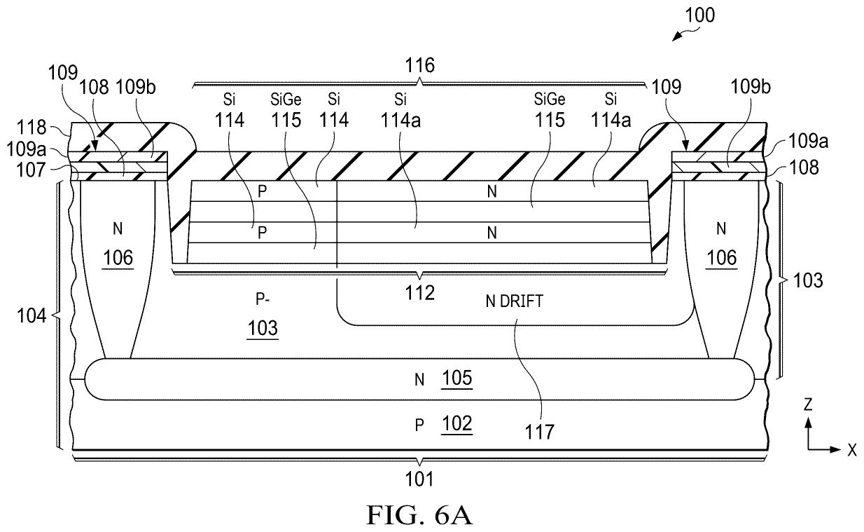

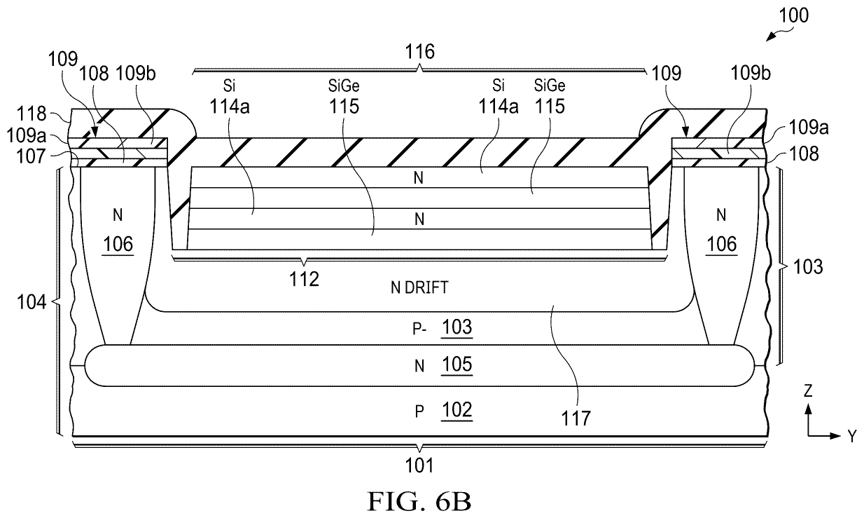

Referring to FIG. 6A and FIG. 6B, cross sections are shown after a STI structure 118 is deposited. The STI structure 118 forms a dielectric gap fill between the nanosheet region 116 and the substrate 104. The STI structure 118 may include the trench sidewall spacer 113 and a deposited oxide, such as formed by a high density plasma (HDP) oxide deposition process.

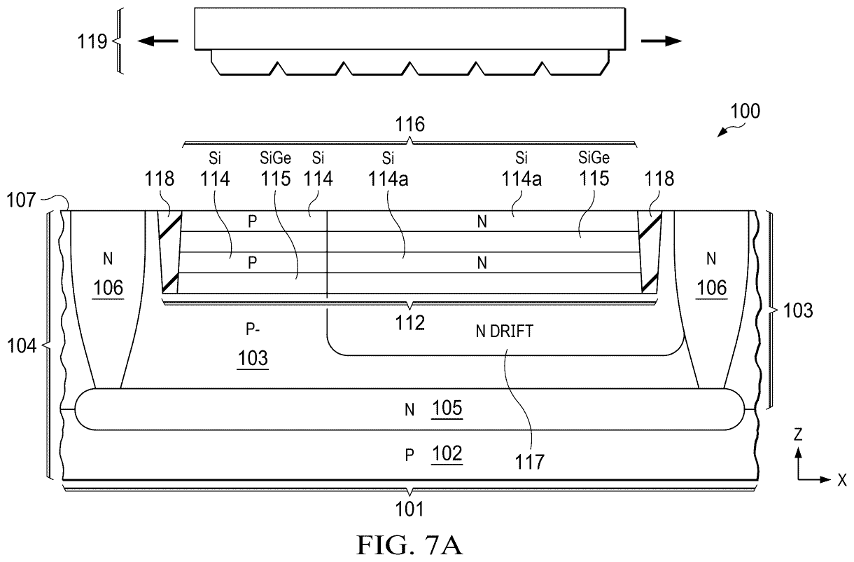

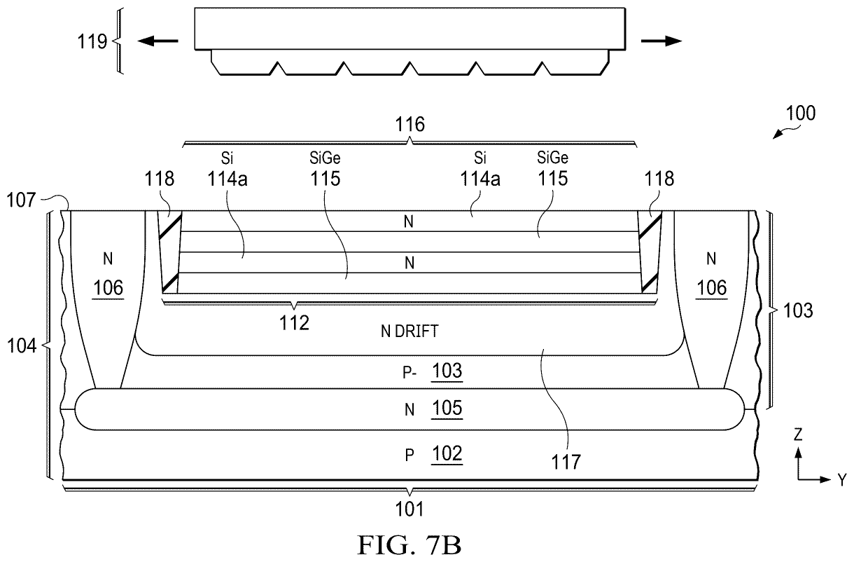

Referring to FIG. 7A and FIG. 7B, cross sections are shown after a chemical mechanical polish (CMP) process 119 has removed the STI structure 118 outside the superlattice sidewall trenches. The STI structure 118 acts as a gap fill between the nanosheet region 116 and the substrate 104. After the CMP process 119, the first hard mask layer 109 and the first pad oxide layer 108 are removed.

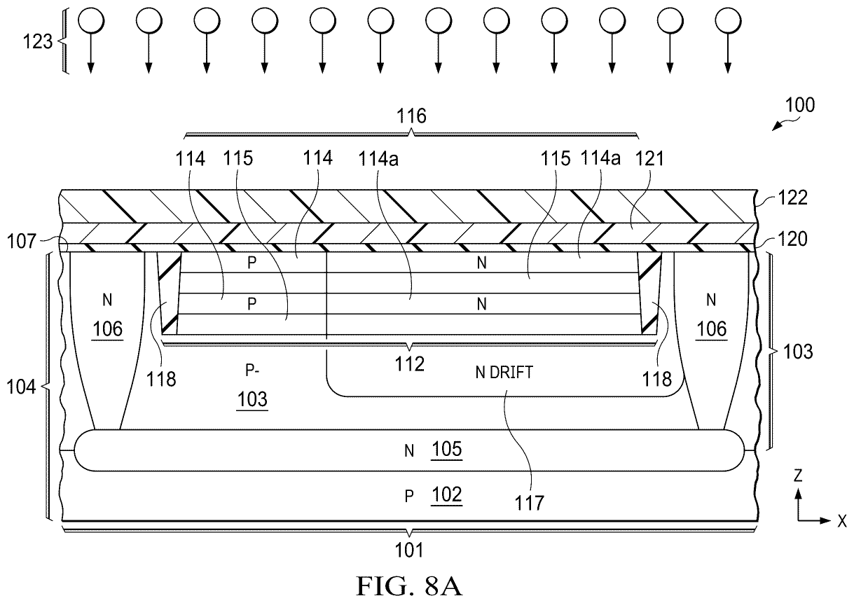

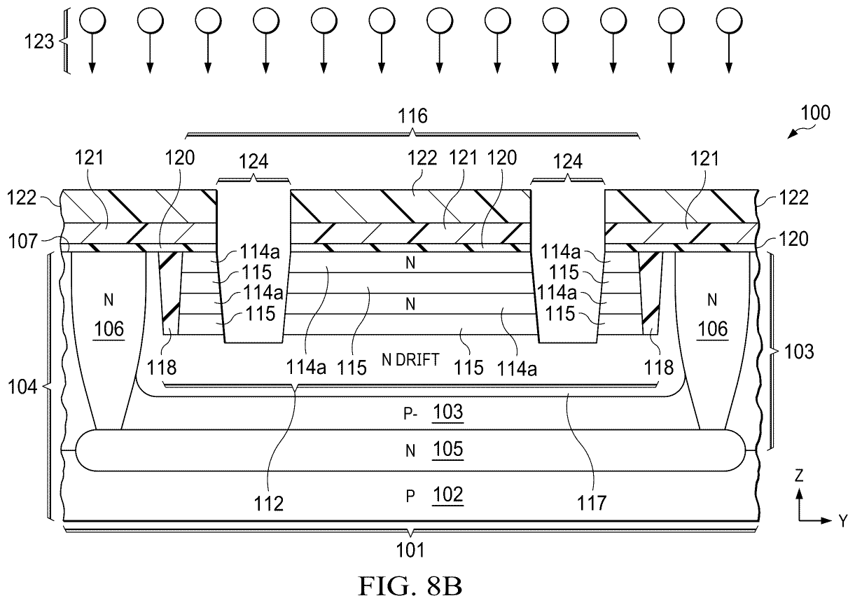

Referring to FIG. 8A and FIG. 8B, cross sections are shown after forming the trenches 124. A second pad oxide layer 120 and a hard mask layer 121 such as SiN or SiON have been formed, and mask layer 122 such as an organic photoresist has been patterned with openings over locations at which the trenches 124 are to be formed. An etch process 123 removes portions of the hard mask layer 121, second pad oxide layer 120, n- doped silicon layers 114a and sacrificial layers 115 under openings in the mask layer 122. The etch process 123 may include multiple steps as needed to remove the different material layers. After the trenches 124 are formed, the mask layer 122 is removed.

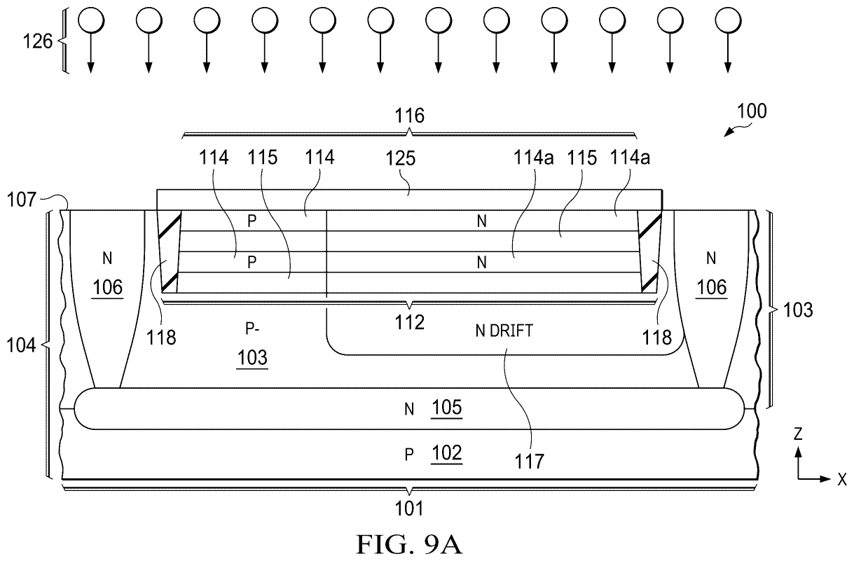

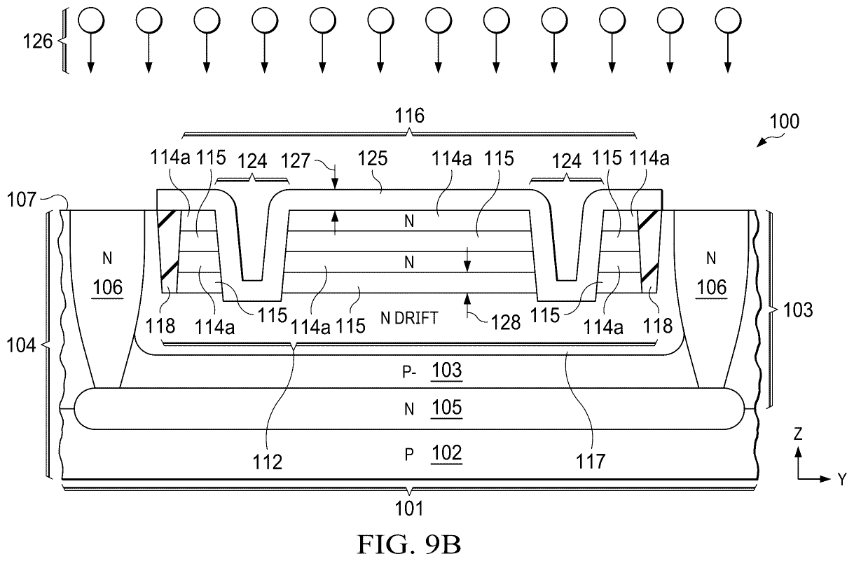

Referring to FIG. 9A and FIG. 9B, cross sections are shown after a sacrificial poly silicon-germanium layer 125, sometimes referred to as a poly-SiGe layer 125, is formed on the top surface 107 of the nanosheet transistor 101 and in the sacrificial polysilicon/germanium trenches 124. After the poly-SiGe layer 125 is formed, a photo pattern step and a plasma etch step (neither specifically shown) are used to remove a portion of the poly-SiGe layer 125 on the top surface 107 outside of the sacrificial polysilicon/germanium trenches 124. The outer border of the poly-SiGe layer 125 is over the STI structure 118. The poly-SiGe layer may be formed by a CVD method or an ALD method. The poly-SiGe layer 125 has a thickness 127 which may be about a same thickness 128, e.g., within ten percent, of the n-doped silicon layers 114a. A process 126 is representative of the growth process of the poly-SiGe layer 125 and the patterning.

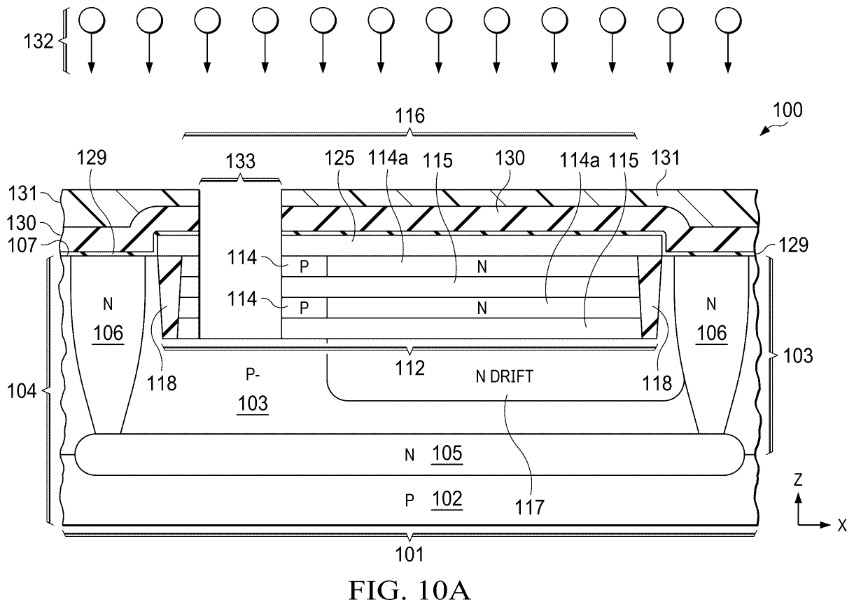

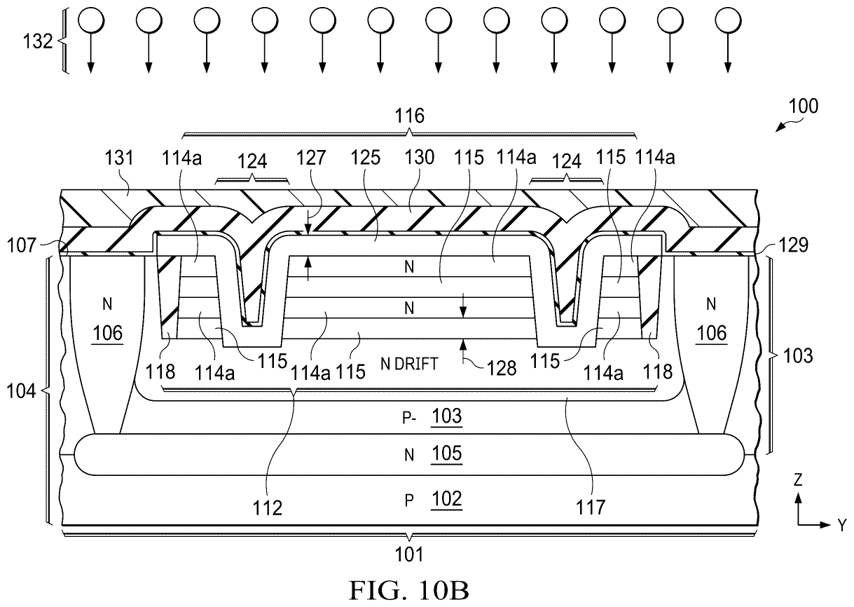

Referring to FIG. 10A and FIG. 10B, cross sections are shown after the formation of a source trench 133. A third pad oxide layer 129 is formed over the top surface 107 of the substrate 104 and the poly-SiGe layer 125. A third hard mask layer 130 is formed on the third pad oxide layer 129. After the formation of a source photolithographic pattern 131, on the third hard mask layer 130, a source trench etch 132 which may include multiple steps may be used to etch the third hard mask layer 130, the third pad oxide layer 129, and the nanosheet region 116 in the open areas of the source photolithographic pattern 131.

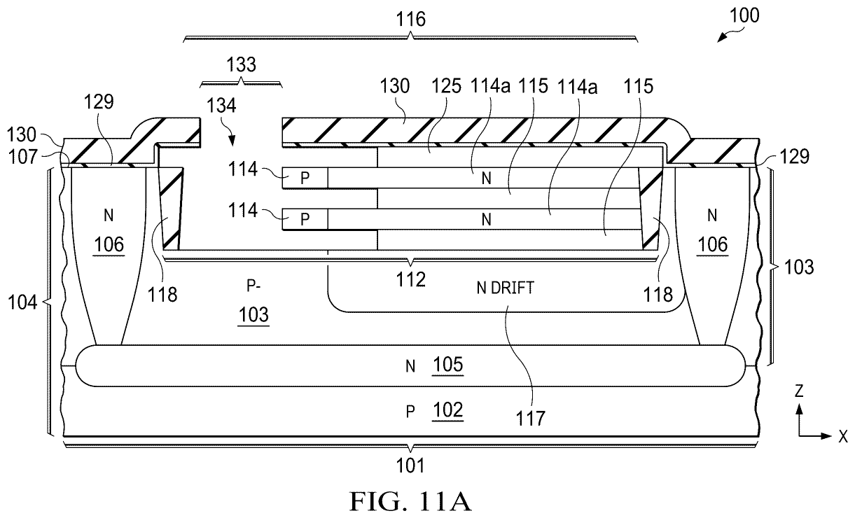

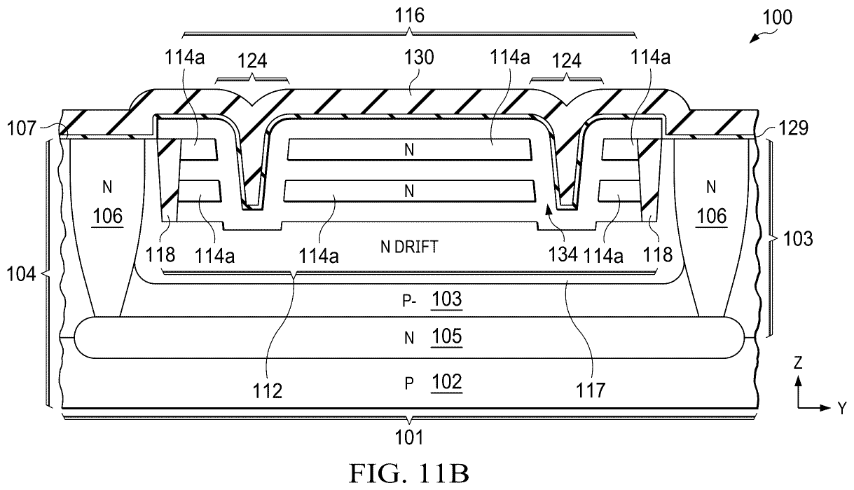

Referring to FIG. 11A and FIG. 11B, cross sections are shown after a plasma etch or a wet etch process (not specifically shown) selectively removes a portion of the sacrificial layers 115 and the poly-SiGe layer 125 of the nanosheet region 116. The sacrificial layers 115 and the poly-SiGe layer 125 are removed via the exposed areas in the source trench 133. The plasma etch or a wet etch process used to remove a portion of the sacrificial layers 115 and the poly-SiGe layer 125 may be a timed etch to control the removal of a portion of the sacrificial layers 115 and the poly-SiGe layer 125 creating first superlattice voids 134 with p-doped remaining portions of the silicon layers 114 and n-doped silicon layers 114a remaining between the first superlattice voids 134. The first superlattice voids 134 leave the remaining portions of the silicon layers 114 and exposed portions of the n-doped silicon layers 114a suspended over the substrate 104 in the region of the silicon layers 114 nearest the source trench 133. After removing of a portion of the sacrificial layers 115 and the poly-SiGe layer 125 nearest the source trench 133, a cleanup process that may include supercritical CO₂ may be employed to remove residues.

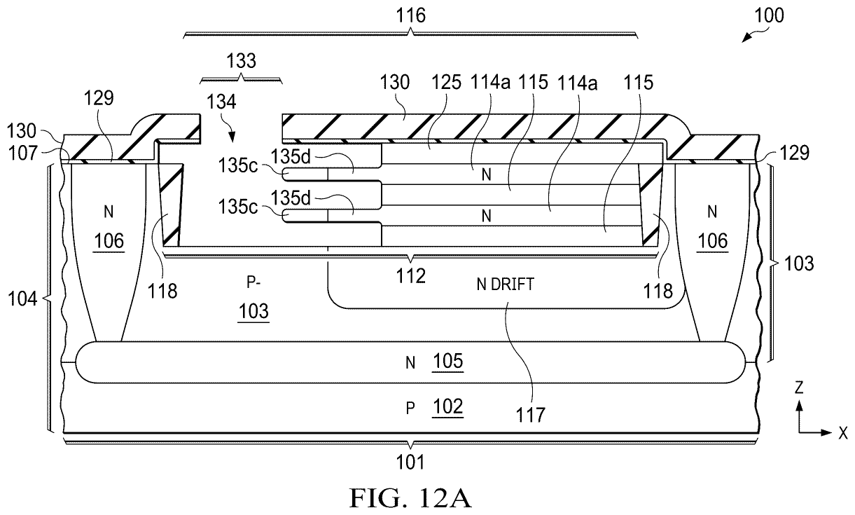

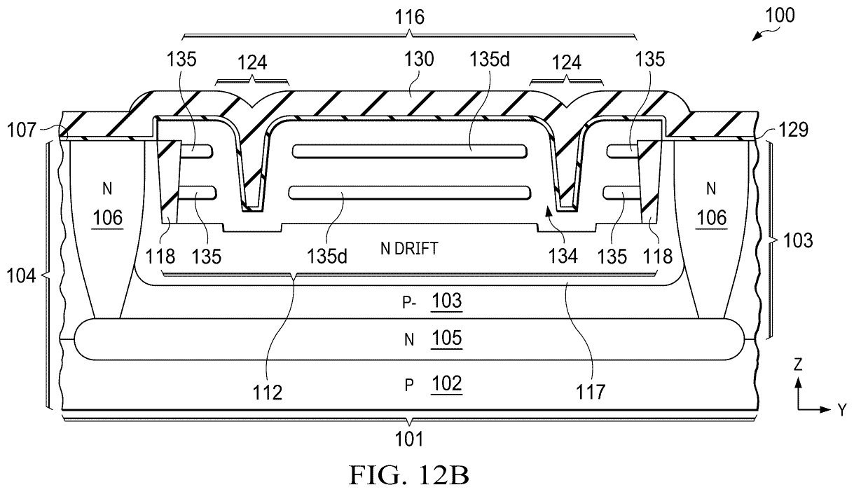

Referring to FIG. 12A and FIG. 12B, cross sections are shown after an optional isotropic etch process (not specifically shown) is used to thin the portion of the silicon layers 114 suspended over the substrate creating p-type nanosheet channel layers 135c and thin n-drift regions 135d. The isotopic etch process may be a vapor phase process with a high partial pressure of HCl, or a CF₄/O₂/He low pressure plasma or similar process. Alternately, a wet etch including HF, hydrogen peroxide and acetic acid or similar chemistry may be used. The isotropic etch removes a portion of the silicon layers 114 and leaves the thinned silicon layers 135 that include channel layers 135c and the thin n-drift regions 135d. Forming the thinned silicon layers 135 in the gate electrode region 158 (see FIG. 1C) from the silicon layers 114 may provide increased mechanical stability during fabrication. The n-doped silicon layers 114a are not thinned in the field plate region 159 (see FIG. 1C) which reduces the sheet resistance of the final drift regions later formed in the field plate region 159. The silicon layers 114 may be trimmed up to 33 percent of their initial thickness as-formed. The thinned channel layers 135c may improve the channel control of the nanosheet transistor 101.

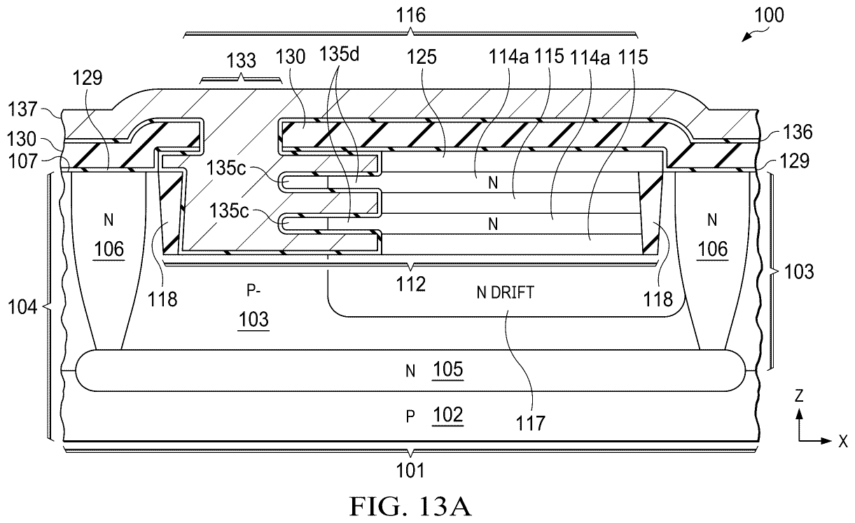

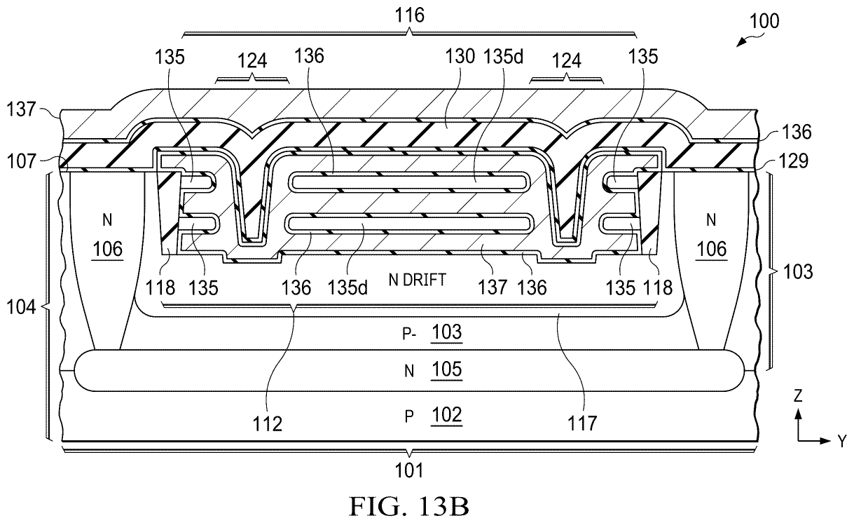

Referring to FIG. 13A and FIG. 13B, cross sections are shown after the gate dielectric layer 136 and a first conductive layer 137, sometimes referred to as a gate electrode layer 137, are formed. The gate dielectric layer 136 is formed on exposed surfaces of the nanosheet transistor 101 such as a portion of the substrate 104, a portion of the sacrificial layers 115, a portion of the poly-SiGe layer 125, the third hard mask layer 130, and the thinned channel layers 135c. The gate electrode layer 137 is formed on the gate dielectric layer 136. The gate dielectric layer 136 may be of a material such as HfO/ZrO, or ZrO₂ or other high-k material with a thickness between 1 nm and 2.5 nm. The gate electrode layer 137 thickness may be such that it fills the first superlattice voids 134. In various examples the gate electrode layer 137 may be TiAlN, TiN or other appropriate material.

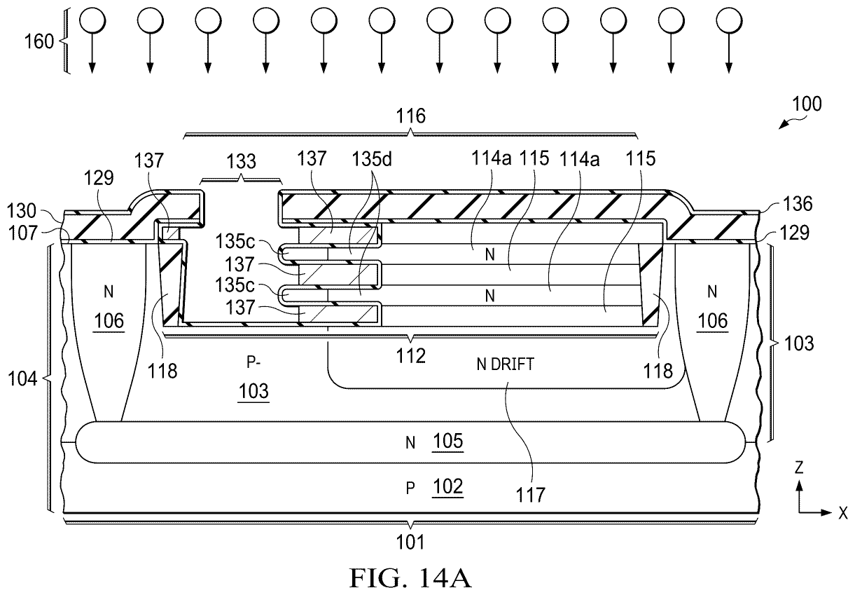

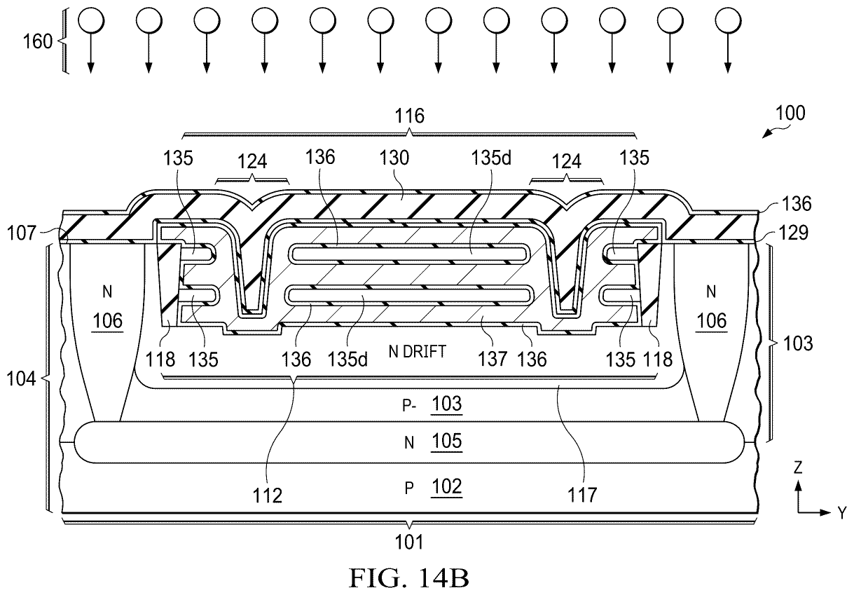

Referring to FIG. 14A and FIG. 14B, cross sections are shown after a gate metal etch process 160 removes a portion of the gate electrode layer 137. The gate metal etch process 160 removes all of the gate electrode layer 137 in the source trench 133, on the gate dielectric layer 136 over the third hard mask layer 130, and a portion of the gate electrode layer 137 between the thinned channel layers 135c. The portion of the gate electrode layer 137 remaining which contacts the thinned channel layers 135c is electrically active in the nanosheet transistor 101, while the portion of the gate electrode layer 137 remaining which is over the STI structure 118 is not electrically active. When the gate dielectric layer 136 is a high-k gate dielectric, the gate dielectric layer 136 may provide additional hard mask margin during the removal of the gate electrode layer 137.

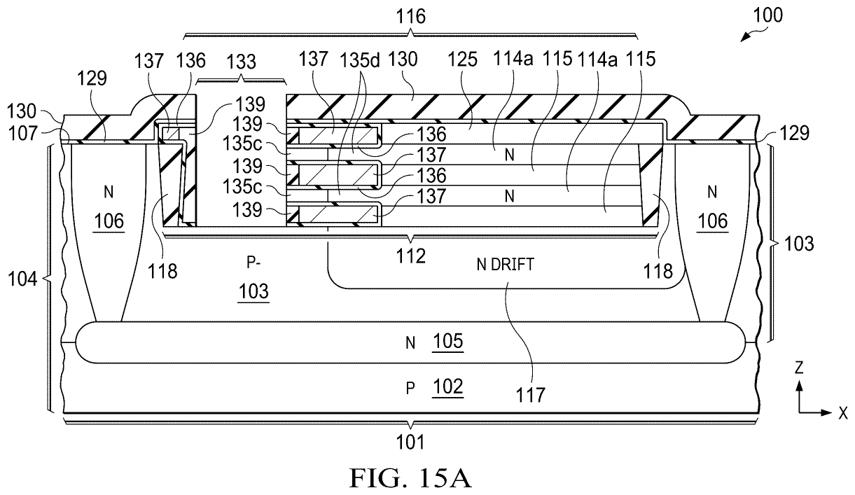

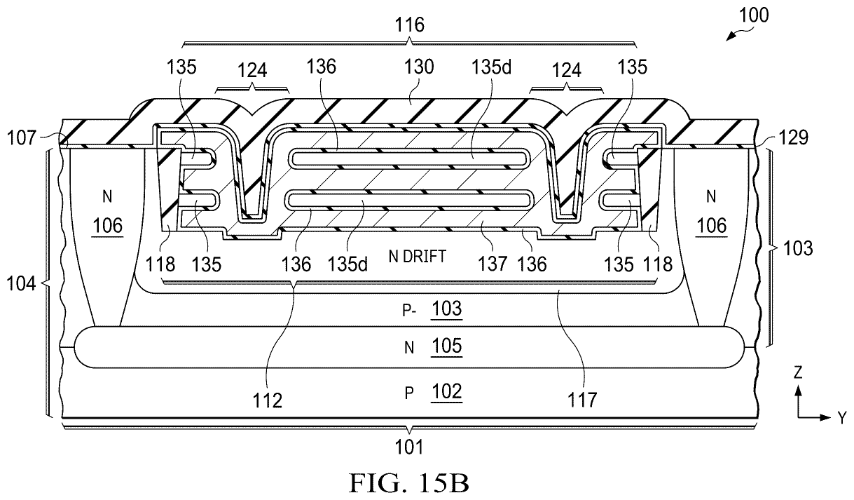

Referring to FIG. 15A and FIG. 15B, cross sections are shown after a conformal dielectric deposition and an anisotropic dielectric etch (neither specifically shown) are used to form the gate electrode spacers 139. When the gate dielectric layer 136 is a high-k gate dielectric it may provide additional etch stop margin compared to the third hard mask layer 130 alone during the anisotropic etch which forms the gate electrode spacers 139. The gate electrode spacers 139 may be silicon nitride, silicon oxynitride, silicon dioxide or other dielectric material. The gate electrode spacers 139 is in front of the plane of the cross section in FIG. 15B. After the gate electrode spacers 139 is formed, the gate dielectric layer 136 is removed over the third hard mask layer 130 and the exposed areas on the substrate 104 in the source trench 133.

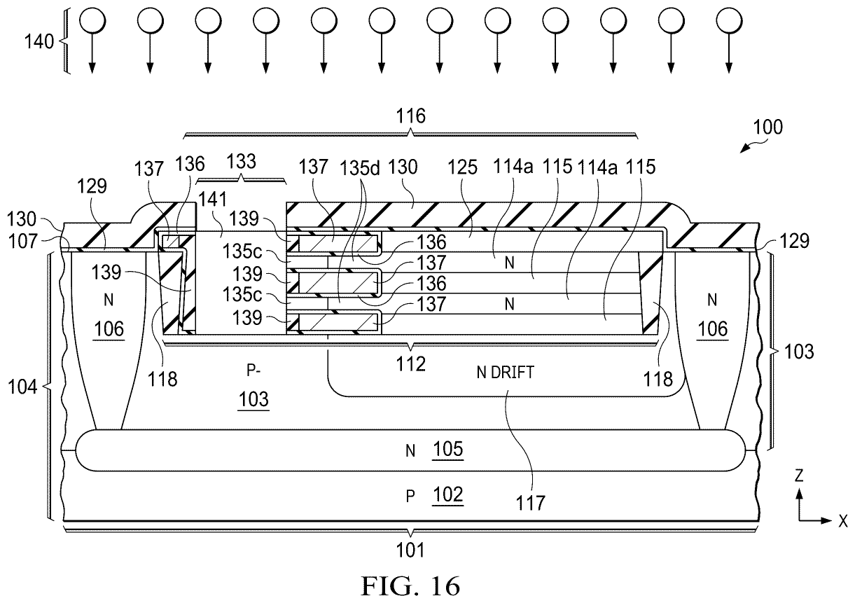

Referring to FIG. 16, a cross section is shown after a selective n-type polysilicon deposition process 140 forms the source region 141. The selective n-type polysilicon deposition process 140 fills the source region 141 with polysilicon with no deposition of polysilicon on the third hard mask layer 130. Alternatively the source region 141 may be formed from a blanket film of polysilicon that fills the source trench 133 and covers the third hard mask layer 130, followed by a polysilicon CMP process.

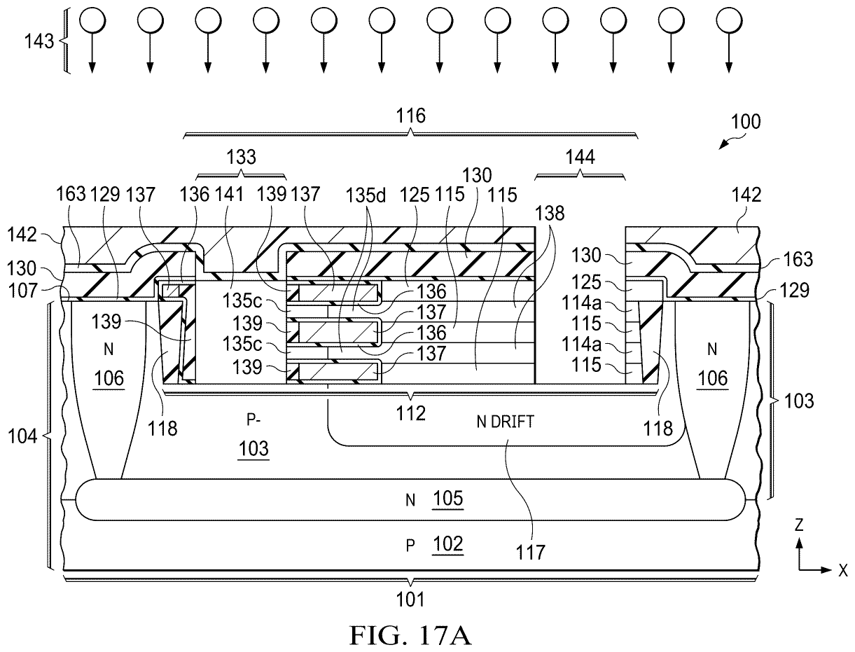

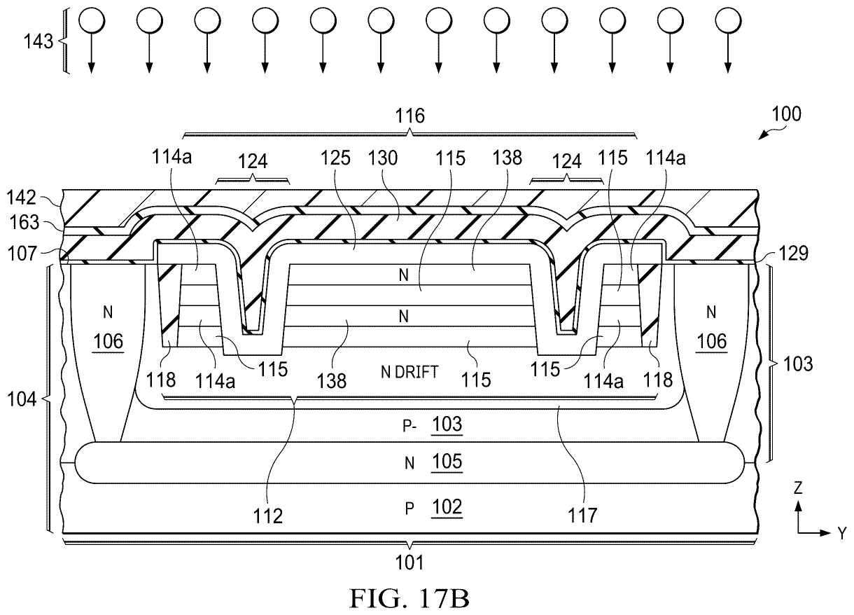

Referring to FIGS. 17A and 17B, cross sections are shown after the formation of a drain trench 144. A fourth hard mask layer 163 is formed on the third hard mask layer 130, and a drain trench photolithographic pattern 142 is formed. A drain trench etch 143, which may include multiple steps may be used to etch the fourth hard mask layer 163, the third hard mask layer 130, the third pad oxide layer 129, and the nanosheet region 116 in the open areas of the drain trench photolithographic pattern 142. The fourth hard mask layer 163 may be thinner than the third hard mask layer 130. After the formation of the drain trench 144, the drain trench photolithographic pattern 142 is removed.

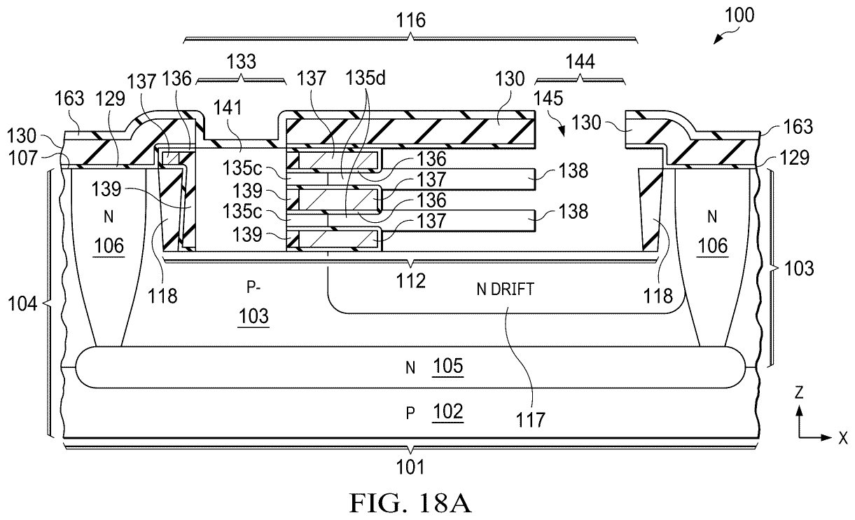

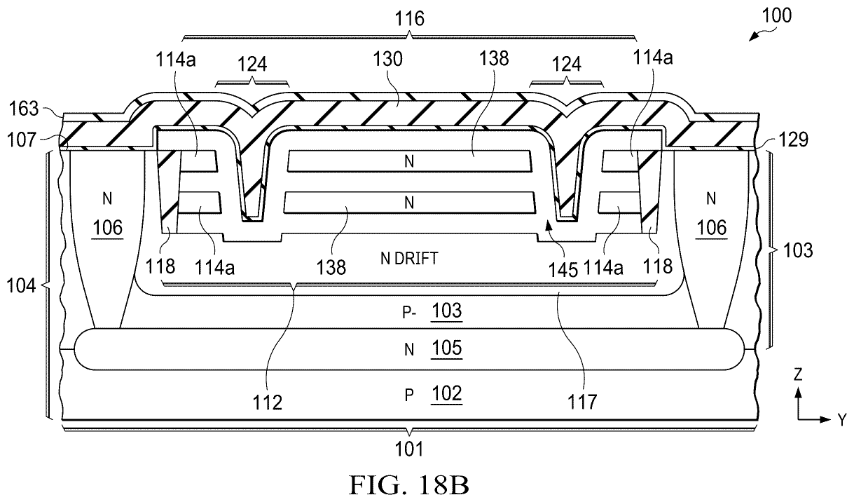

Referring to FIGS. 18A and 18B, cross sections are shown after a plasma etch or a wet etch process selectively removes a portion of the sacrificial layers 115 and the poly-SiGe layer 125 of the nanosheet region 116 starting from the drain trench 144. The removal of the sacrificial layers 115 and the poly-SiGe layer 125 form second superlattice voids 145. During the formation of the second superlattice voids 145, all of the sacrificial layers 115 material is removed with the second superlattice voids 145 extending from the drain trench 144 to the gate dielectric layer 136. The second superlattice voids 145 leaves a portion of the n-doped silicon layers 114a remaining, which may now be referred to as drain drift layers 138. The drain drift layers 138 are suspended over the substrate 104 in the second superlattice voids 145 between the gate dielectric layer 136 and the drain trench 144. The drain drift layers 138 are attached through the gate dielectric layer 136 layer and the gate electrode layer 137. After removing the sacrificial layers 115 nearest the drain trench 144, a cleanup process that includes supercritical CO₂ may be employed to remove residues.

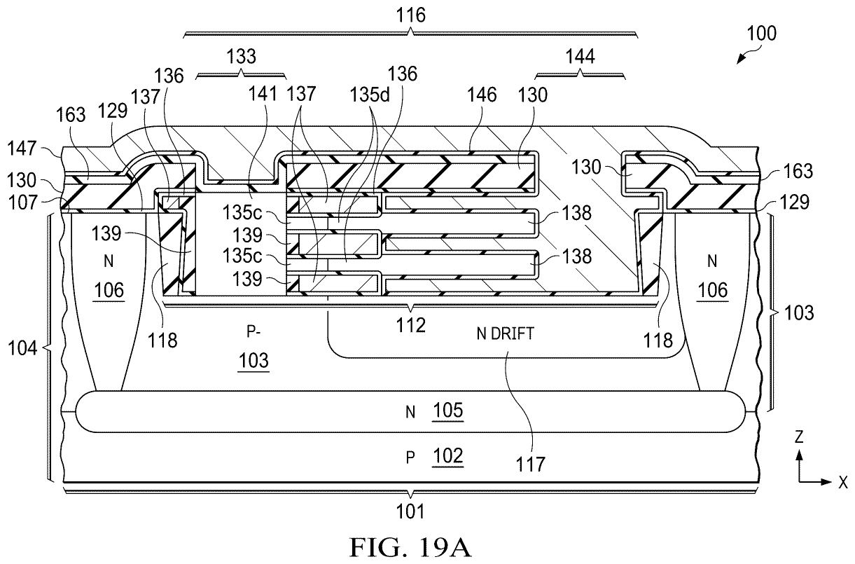

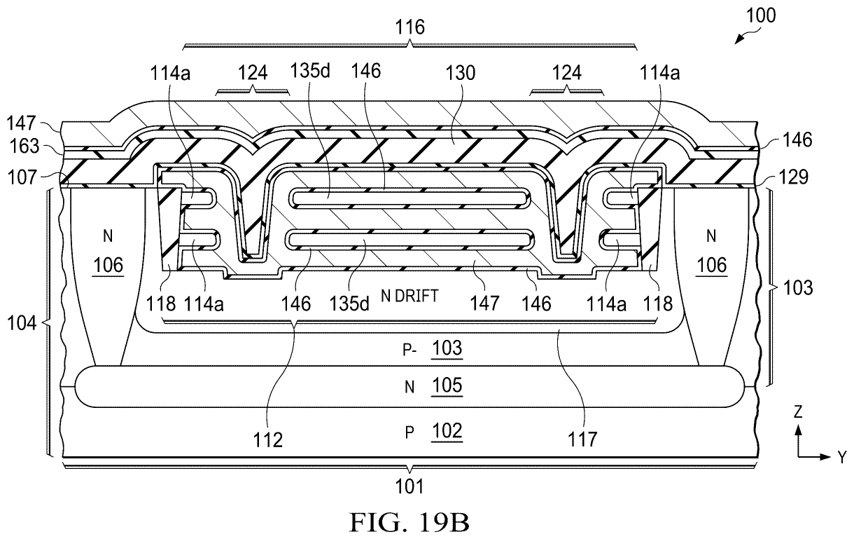

Referring to FIG. 19A and FIG. 19B, cross sections are shown after the field relief dielectric layer 146 and the field plate layer 147 are formed. The field relief dielectric layer 146 is thicker than the gate dielectric layer 136 which enabling the nanosheet transistor 101 to function at higher voltages. The field relief dielectric layer 146 is formed on exposed surfaces of the nanosheet transistor 101 such as a portion of the substrate 104, the n-doped silicon layers 114a, and the fourth hard mask layer 163. The field plate layer 147 is formed on the field relief dielectric layer 146. The field relief dielectric layer 146 may be between 2.5 nm and 10 nm. The field plate layer 147 may be thick enough to fill the second superlattice voids 145. For the example device, an NMOS LDMOS, the field plate layer 147 may be TaN or another material with a work function higher than the work function of the gate electrode layer 137. For a PMOS device, the field plate layer 147 may be tungsten or another metal layer material with a work function less than the gate electrode layer 137.

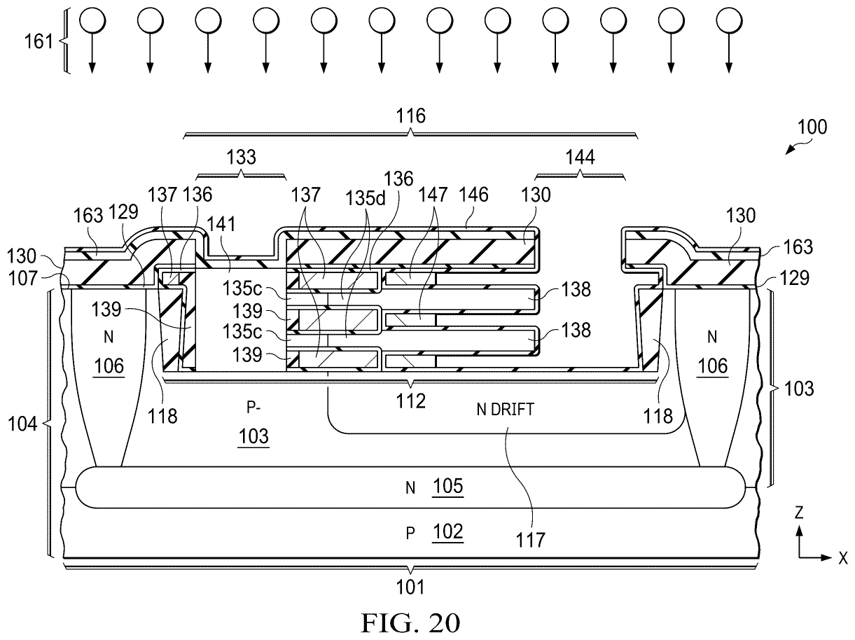

Referring to FIG. 20, a cross section is shown after a field plate metal etch process 161 removes a portion of the field plate layer 147. The field plate metal etch process removes all of the field plate layer 147 in the drain trench 144 and over the fourth hard mask layer 163. The field plate metal etch process 161 removes a portion of the field plate layer 147 between the n-doped silicon layers 114a nearest the drain trench 144, and leaves a portion of the field plate layer 147 between the nanosheets in the region nearest the source region 141. The amount of the field plate layer 147 remaining after the field plate metal etch process may be adjusted by adjusting the time of the field plate metal etch process. When the field relief dielectric layer 146 is a high-k dielectric, the field relief dielectric layer 146 may provide additional hard mask margin during the removal of the field plate layer 147.

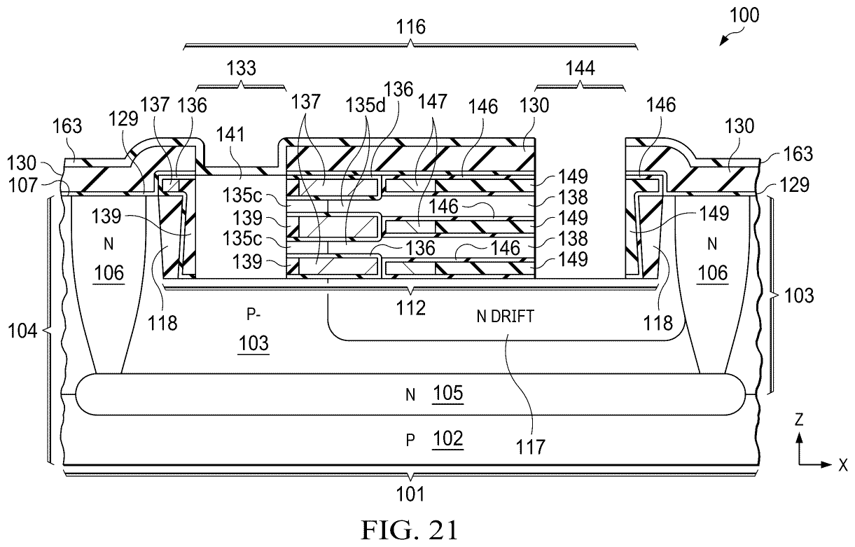

Referring to FIG. 21, a cross section is shown after a conformal dielectric deposition and an anisotropic dielectric etch (neither specifically shown) are used to form the field plate spacers 149. When the field relief dielectric layer 146 is a high-k gate dielectric it may provide additional etch stop margin when combined with the fourth hard mask layer 163 and the third hard mask layer 130 alone during the anisotropic etch which forms the field plate spacers 149. The field plate spacers 149 may be silicon nitride, silicon oxynitride, silicon dioxide or other dielectric material. After the field plate spacers 149 is formed, the field relief dielectric layer 146 is removed over the fourth hard mask layer 163 and the exposed areas on the substrate 104 in the drain trench 144.

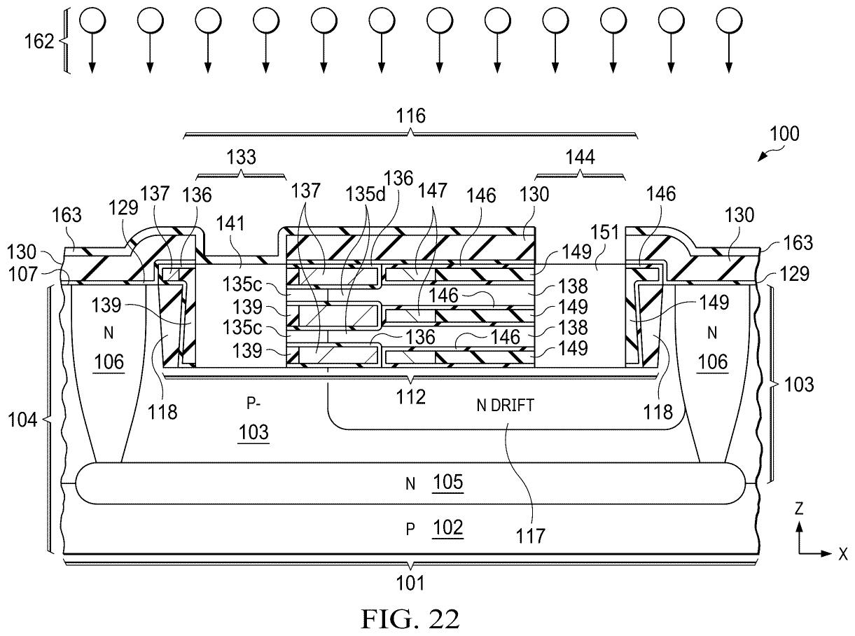

Referring to FIG. 22, a cross section is shown after a selective n-type polysilicon deposition process 162 forms the drain region 151. The selective n-type polysilicon deposition process 162 fills the drain region 151 with polysilicon with no deposition of polysilicon on the fourth hard mask layer 163. The fourth hard mask layer 163 prevents n-type polysilicon deposition on the source region 141. An alternative method to form the drain region 151 may be to form a blanket film of polysilicon which also fills the drain trench 144 and form the drain region 151 through a polysilicon CMP process.

Additional conventional processing may be performed to form the PMD layer 153, a source contact 154, a drain contact 155, a gate contact 156 and metal terminals 157 that are illustrated in FIG. 1C.

While various examples of the present disclosure have been described above, it should be understood that they have been presented by way of example and not limitation. As such, although foregoing examples are described to use various resist layers (e.g., photoresist or photomask layers) to perform various process steps (e.g., implant steps or etch steps), the present disclosure is not limited thereto. For example, one or more hard masks (including one or more layers) may be patterned to define various regions for subsequent process steps to be applied (e.g., regions for receiving dopant atoms, regions to block etchants). Moreover, the resist layers may include multi-level resists instead of a single-level resist in some examples. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the following claims and their equivalents.

What is claimed is:

1. A microelectronic device, comprising:
a first doped semiconductor region and a second doped semiconductor region extending into a semiconductor substrate, the first and second doped semiconductor regions having a first conductivity type and the semiconductor substrate having an opposite second conductivity type;
a semiconductor layer contacting the first doped semiconductor region and the second doped semiconductor region;
a first dielectric layer contacting the first doped semiconductor region;
a second dielectric layer contacting the second doped semiconductor region;
a first conductive layer contacting the first dielectric layer wherein the first dielectric layer separates the first conductive layer from the first doped semiconductor region;
a third dielectric layer separating the first conductive layer from the semiconductor layer;
a second conductive layer contacting the second dielectric layer wherein the second dielectric layer separates the second conductive layer from the second doped semiconductor region; and
a fourth dielectric layer separating the second conductive layer from the semiconductor layer, wherein the second dielectric layer and the fourth dielectric layer are between the first conductive layer and the second conductive layer.

2. The microelectronic device as recited in claim 1, wherein the semiconductor layer is one of first and second semiconductor layers connected between the first doped semiconductor region and the second doped semiconductor region, the first and second conductive layers, the third dielectric layer, and the fourth dielectric layer being between the first and second semiconductor layers.

3. The microelectronic device as recited in claim 1, wherein the first doped semiconductor region is a source region and the second doped semiconductor region is a drain region, the source region and the drain region having a first average dopant concentration, and further comprising a drain drift region having the first conductivity type and a lower second dopant concentration in the semiconductor layer and extending from the drain region toward the source region.

4. The microelectronic device as recited in claim 1, wherein the third dielectric layer and the fourth dielectric layer have a dielectric constant greater than 3.9.

5. The microelectronic device as recited in claim 1, wherein the first conductive layer and the second conductive layer have work function greater than 3.9 eV.

6. The microelectronic device as recited in claim 1, wherein the first conductive layer and the second conductive layer are selected from the group consisting of TiAlN, TiN, TaN, Al, TaSiN, MoN and W.

7. The microelectronic device recited in claim 1, wherein the semiconductor layer has a thickness greater than 10 nm.

8. The microelectronic device as recited in claim 1, wherein the fourth dielectric layer is thicker than the third dielectric layer.

9. The microelectronic device as recited in claim 1, wherein a gate contact is electrically connected to the first conductive layer and the second conductive layer.

10. A method of forming a microelectronic device comprising:
forming a trench in a semiconductor substrate having a first conductivity type;
forming a semiconductor nanosheet stack in the trench including a semiconductor layer and a sacrificial layer;
forming a source trench in the semiconductor nanosheet stack and removing a portion of the sacrificial layer contacting the source trench and exposing a portion of the semiconductor layer nearest the source trench;
forming a third dielectric layer contacting the semiconductor layer,
forming a first conductive layer contacting the third dielectric layer;
forming a first dielectric layer between the first conductive layer and the source trench;
forming a first doped semiconductor region by filling the source trench with a first doped semiconductor of the first conductivity type, the first doped semiconductor being a source region;
forming a drain trench in the semiconductor nanosheet stack and removing the sacrificial layer contacting the drain trench exposing a portion of the semiconductor layer nearest the drain trench;
forming a fourth dielectric layer on the semiconductor layer;
forming a second conductive layer on the fourth dielectric layer;
forming a second dielectric layer between the second conductive layer and the drain trench; and
forming a second doped semiconductor region by filling the drain trench with a second doped semiconductor of the first conductivity type, the second doped semiconductor being a drain region.

11. The method of claim 10, wherein forming the semiconductor nanosheet stack includes forming first and second semiconductor layers, including the sacrificial layer between the first and second semiconductor layers.

12. The method of claim 10, further comprising forming a drain drift region having the first conductivity type and an average dopant concentration less than the drain region in the semiconductor substrate and extending from the drain region toward the source region.

13. The method of claim 10, comprising forming the third dielectric layer and the fourth dielectric layer with a dielectric constant greater than 3.9.

14. The method of claim 10, comprising forming the first conductive layer and the second conductive layer having a work function greater than 3.9 eV.

15. The method of claim 10, comprising forming the first conductive layer and the second conductive layer are selected from the group consisting of TiAlN, TiN, TaN, Al, TaSiN, MoN and W.

16. The method of claim 10, comprising forming the semiconductor layer having a thickness greater than 10 nm.

17. The method of claim 10, comprising forming the fourth dielectric layer having a thickness than the third dielectric layer.

18. The method of claim 10, comprising forming a gate contact electrically in connect with the first conductive layer and the second conductive layer.
